(19) United States
(12) Patent Application Publication
(10) Pub. No.: US 2026/0160957 A1
(43) Pub. Date: Jun. 11, 2026

(54) OPTICAL NETWORK INTERFACE CARD AND OPTICAL TRANSMISSION APPARATUS

(71) Applicant: AIP Inc., New Taipei City (TW)

(72) Inventor: Chia LEE, New Taipei City (TW)

(73) Assignee: AIP Inc., New Taipei City (TW)

(21) Appl. No.: 19/322,757

(22) Filed: Sep. 9, 2025

Related U.S. Application Data
(60) Provisional application No. 63/730,669, filed on Dec. 11, 2024.
(60) Provisional application No. 63/746,293, filed on Jan. 17, 2025.

(51) Int. Cl. G02B 6/42; G02B 6/36; H05K 1/02

(52) U.S. Cl. CPC G02B 6/4201; G02B 6/3624; H05K 1/0274

(57) ABSTRACT

An optical network interface card, adapted for use with at least an optical cable unit, includes a load board, a network chip disposed on the load board, at least an optical adapter installed on the load board for connection with the optical cable unit, a photonic integrated circuit disposed on the load board and electrically connected to the network chip, and an optical coupling assembly installed on the load board and connected between the optical adapter and the photonic integrated circuit.

### CROSS REFERENCE TO RELATED APPLICATIONS

This application claims the benefits of priority under 35 USC § 119(e) of U.S. Provisional Ser. No. 63/730,669 filed on Dec. 11, 2024 and of U.S. Provisional Ser. No. 63/746,293 filed on Jan. 17, 2025. The contents of the above applications are all incorporated by reference as if fully set forth herein in their entirety.

### BACKGROUND OF INVENTION

### 1. Field of Invention

The present invention relates to a technical field of optical adapters, and particularly to an optical network interface card and an optical transmission apparatus.

### 2. Related Art

Generally, data processing devices, such as switches, servers, etc., are equipped with optical fiber network cards for network connecting. Typically, backplanes of optical fiber network cards are provided with one or more ports, which are suitable for cables, such as direct attach cables (DAC) or active optical cables (AOC) with small form-factor pluggable (SFP) transceivers, and serve as the medium for optical signal transmission. As is well known, SFP is a hot-pluggable network interface module used for both telecommunication and data communication applications. Conventional optical fiber network cards are equipped with modular slots for SFP interfaces for insertion of SFP transceivers. Typically, SFP transceivers are at least six centimeters long. In other words, modular slots for SFP interfaces take up a significant portion of conventional optical fiber network cards, inevitably resulting in a larger overall size of optical fiber network cards. However, due to the limited internal space of data processing devices, the larger size of conventional optical fiber network cards remains an obstacle to the arrangement of internal components, thus adversely affecting the operational efficiency of optical fiber network cards.

### SUMMARY OF INVENTION

An object of the present application is to provide an optical network interface card being compact in size.

Another object of the present application is to provide an optical network interface card capable of enhancing the flexibility in component arrangement.

Another object of the present application is to provide an optical transmission apparatus for optical transmission through an optical network interface card and a pluggable optical cable unit.

To achieve at least one of the above-mentioned objects, the present application provides an optical network interface card, adapted for use with at least an optical cable unit, and comprising a load board, a network chip disposed on the load board, at least an optical adapter installed on the load board for connection with the optical cable unit, a photonic integrated circuit disposed on the load board and electrically connected to the network chip, and an optical coupling assembly installed on the load board and connected between the optical adapter and the photonic integrated circuit.

Optionally, the optical coupling assembly comprises a fiber array unit comprising a connecting head, a ferrule element, and a plurality of optical fibers connected between the connecting head and the ferrule element. The connecting head is connected to the optical adapter, and the ferrule element is positioned to correspond to a transmitting portion included in the photonic integrated circuit.

Optionally, the optical coupling assembly further comprises a detachable connector, a connecting base, and a waveguide substrate, wherein the detachable connector is detachably connected to the connecting base and comprises the ferrule element, and the waveguide substrate is positioned in the connecting base, in optical alignment between the optical fibers and the photonic integrated circuit.

Optionally, the detachable connector further comprises a fastening member movably assembled with the ferrule element, the connecting base comprises a positioning protrusion, and the fastening member is configured to detachably engage with the positioning protrusion.

Optionally, the detachable connector further comprises a plurality of limiting members connected between the fastening member and the ferrule element, the fastening member defines a fastening groove located above the ferrule element, and the connecting base comprises a base body and a retaining member extending from the base body. The positioning protrusion is positioned on the retaining member, and the fastening groove is detachably fastened with the positioning protrusion to connect the detachable connector to the connecting base.

Optionally, the optical coupling assembly comprises a connecting base connected between the optical adapter and the photonic integrated circuit, and a waveguide substrate positioned in the connecting base in optical alignment between the optical cable unit and the photonic integrated circuit.

Optionally, the optical network interface card further comprises at least an elevated portion, an upper board, and a flexible cable, wherein the elevated portion is disposed on the load board to correspond to the optical adapter and is configured to support the upper board at a predetermined height above the load board, the photonic integrated circuit is mounted on the upper board, the flexible cable has one end connected to the upper board, and another end connected to the load board.

Optionally, the optical adapter comprises an internal socket positioned over the load board and comprising a root portion, a block, and an internal groove positioned between the root portion and the block and exposed to the block, and the connecting head is detachably inserted into the internal groove.

The present application further provides an optical transmission apparatus, comprising an optical network interface card and at least an optical cable unit. The optical network interface card comprises a load board, a network chip disposed on the load board, at least an optical adapter installed on the load board, a photonic integrated circuit disposed on the load board and comprising a signal transmitting portion, and an optical coupling assembly installed on the load board and connected between the optical adapter and the signal transmitting portion. The optical cable unit is detachably plugged to the optical adapter and optically connected with the photonic integrated circuit through the optical coupling assembly.

Optionally, the optical cable unit comprises an optical cable and a plug device positioned at an end of the optical cable and detachably plugged to the optical adapter.

In the present application, the optical network interface card and the optical transmission apparatus are equipped with the photonic integrated circuit as the medium for light signal transmission, which eliminates the need for space to accommodate a conventional optical transceiver (not shown) connected to the optical cable, thus making the optical network interface card more compact, optimizing both the size and the efficiency of the entire optical network interface card and the optical transmission apparatus, thereby improving the utilization of the limited internal space in data processing devices.

### BRIEF DESCRIPTION OF DRAWINGS

To describe the technical solutions in the embodiments of the present application more clearly, the accompanying drawings used in the embodiments are briefly described below. It should be noted that the drawings illustrate only some embodiments of the present application, and those skilled in the art may derive other drawings therefrom without departing from the scope of the present application.

FIG. 1 is a schematic perspective view of an optical network interface card in accordance with an embodiment of the present application.

FIG. 2 is a schematic perspective view showing an optical transmission apparatus in accordance with an embodiment of the present application.

FIG. 3 is a schematic cross-sectional view of FIG. 2.

FIG. 4 is a schematic perspective view of an optical network interface card in accordance with an embodiment of the present application.

FIG. 5 is a schematic perspective view showing an optical transmission apparatus in accordance with an embodiment of the present application.

FIG. 6 is a schematic cross-sectional view of FIG. 5.

FIG. 7 is a schematic exploded view showing a detachable connector and a connecting base of in accordance with an embodiment of the present application.

FIG. 8 is a schematic perspective view showing an optical transmission apparatus in accordance with an embodiment of the present application.

### DESCRIPTION OF PREFERRED EMBODIMENTS

The following embodiments refer to the accompanying drawings for exemplifying specific implementable embodiments of the present invention. Directional terms described by the present invention, such as upper, lower, front, back, left, right, inner, outer, side, etc., are only directions by referring to the accompanying drawings, and thus the used directional terms are used to describe and understand the present invention, but the present invention is not limited thereto.

It should be understood that, although the terms first, second, etc. may be used herein to describe various elements, these elements should not be limited by these terms. Unless indicated otherwise, these terms are only used to distinguish one element from another element. Thus, for example, a first element, a first component, or a first section could be termed as a second element, a second component or a second section without departing from the teachings of the present application.

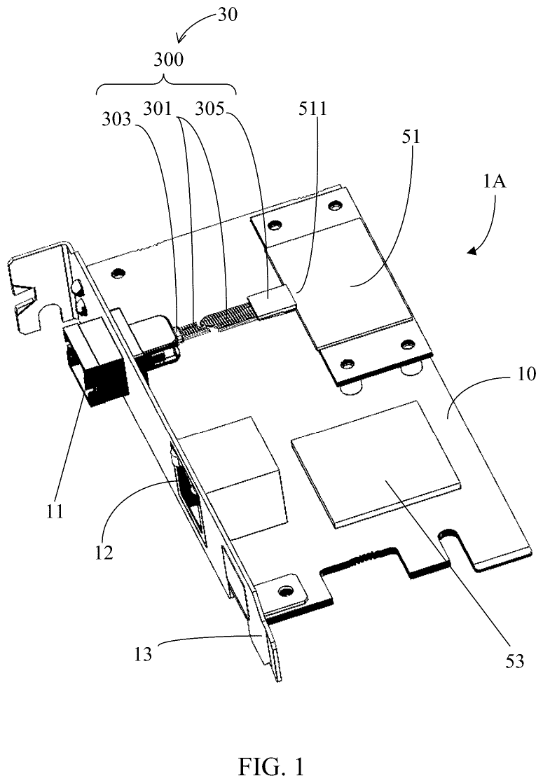

The present application provides an optical network interface card and an optical transmission apparatus that enable optical transmission for servers, switches, or other data processing devices that are equipped with serial bus interfaces, such as peripheral component interconnect express (PCIe) bus, for use with the optical network interface card. Referring to FIG. 1, showing a schematic perspective view of an optical network interface card 1A in accordance with an embodiment of the present application, the optical network interface card 1A includes a load board 10, a plurality of optical adapters 11 and 12 spaced apart from each other and installed on the load board 10, an optical coupling assembly 30 installed on the load board 10 and positioned corresponding to the optical adapter 11, a photonic integrated circuit 51 disposed on the load board 10, and a network chip 53 spaced apart from the photonic integrated circuit 51 on the load board 10. The network chip 53 is electrically connected with the photonic integrated circuit 51 and is responsible for data processing, network communication bridging, etc. In detail, the network chip 53 is configured to perform actions including analyzing the data from received electrical signals already converted from optical signals by the photonic integrated circuit and sending the data to host systems, such as switches or servers. In some embodiments, a strip plate-shaped holder 13 is mounted on the load board 10 and forms a plurality of connecting ports for positioning the optical adapters 11 and 12. In other embodiments (not shown), the optical adapters 11 and 12 may be disposed directly on the load board 10 without the use of the holder 13.

In this embodiment, the optical adapter 11 is adapted for connection with an optical cable for light signal transmission, and the optical adapter 12 is adapted for connection with a cable for electrical signal transmission, such as a cable of RJ 45 connector. As shown in FIG. 1, the optical coupling assembly 30 includes a plurality of components that are connected between the optical adapter 11 and a signal transmitting portion 511 formed on the photonic integrated circuit 51. Specifically, the signal transmitting portion 511 includes a plurality of light paths (not shown) and is configured to enable light signal transmission between the optical coupling assembly 30 and the photonic integrated circuit 51.

As shown in FIG. 1, the optical coupling assembly 30 includes a connecting head 303, a ferrule element 305, and a plurality of optical fibers 301 that jointly form a fiber array unit 300. It is noted that part of the optical fibers 301 are not shown for clarity. Specifically, the connecting head 303 is disposed on an end of each of the optical fibers 301 and pluggable to the optical adapter 11. The ferrule element 305 is disposed on the other ends of the optical fibers 301 and is positioned to correspond to the transmitting portion 511. In this embodiment, the ferrule element 305 is permanently and directly connected to the transmitting portion 511 of the photonic integrated circuit 51.

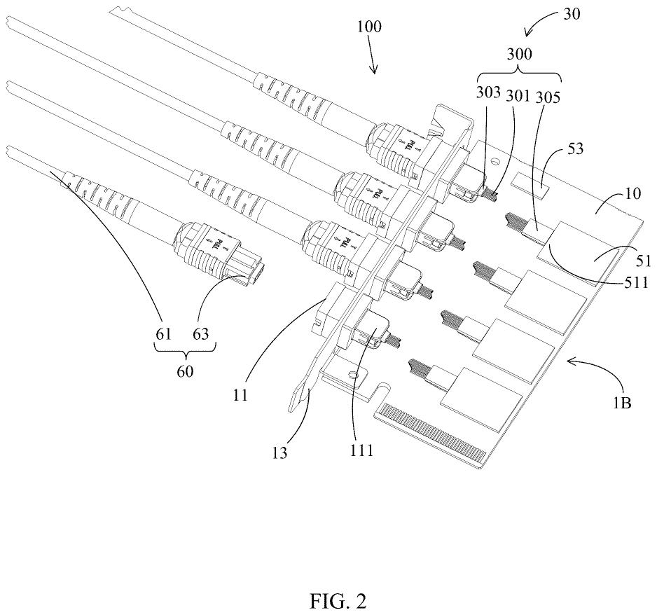

Referring to FIG. 2, which is a schematic perspective view showing an optical transmission apparatus 100 in accordance with an embodiment of the present application, the optical transmission apparatus 100 includes an optical network interface card 1B and a plurality of optical cable units 60. The main differences between the optical network interface card 1B and the optical network interface card 1A are that four optical adapters 11, four optical coupling assemblies 30, and four photonic integrated circuits 51 are provided, without the presence of the optical adapter 12 for the RJ 45 connector. As shown in FIG. 2, the optical cable units 60 are detachably plugged into the optical adapters 11, respectively. Each of the optical cable units 60 includes an optical cable 61 and a plug device 63. In this embodiment, the plug device 63 has a multi-fiber push on (MPO) structure. In this manner, light signals are transmitted between the optical cable unit 60 and the photonic integrated circuit 51 through the respective optical coupling assembly 30.

In this embodiment, the photonic integrated circuit 51 and the network chip 53 may be wire-bonded to the load board 10. The photonic integrated circuit 51 is configured for optical-to-electrical signal conversion and electrical-to-optical signal conversion. In some embodiments, the photonic integrated circuit 51 is preferably a silicon photonic integrated circuit and may be made of a silicon-based material. Specifically, the photonic integrated circuit 51 may include at least a light detection module for receiving light, a built-in or external light source module for emitting light, and a plurality of active components and passive components (not shown), such as, but not limited to filters or multiplexing structures, optical power distribution structures, optical fiber output and input structure, and light modulation structure. Since the present application does not emphasize the detailed structure of the active and passive optical components, which are known to those skilled in the art, these components will not be described in detail here.

As described above, by using the optical coupling assembly 30 and the photonic integrated circuit 51 mounted on the load board 10, the optical network interface cards 1A and 1B can be reduced in size, as they eliminate the need for space to accommodate a conventional optical transceiver (not shown) connected to the optical cable unit 60, thereby making the optical network interface cards 1A and 1B more compact and efficient.

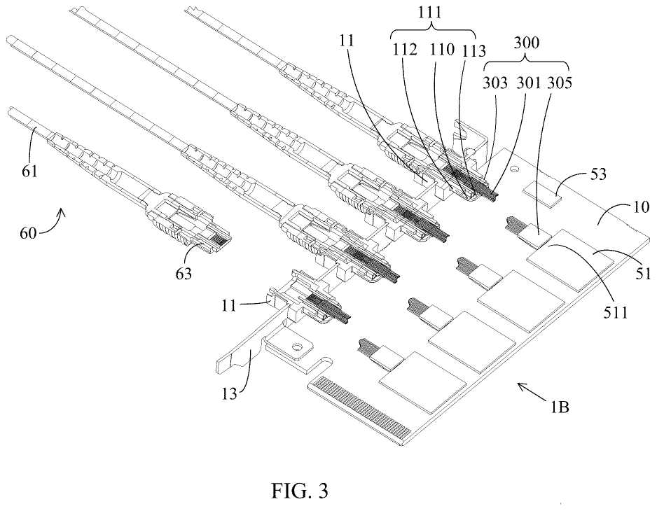

Referring to FIG. 3, illustrating a schematic cross-sectional view of the optical network interface card 1B shown in FIG. 2, specifically highlighting lower portions of the optical adapter 11 and the optical cable unit 60. The optical adapter 11 includes an internal socket 111 positioned over the load board 10. Specifically, the internal socket 111 includes a root portion 112, a block 113, and an internal groove 110 positioned between the root portion 112 and the block 113. In detail, the root portion 112 is positioned close to the holder 13, and the internal groove 110 extends through the optical adapter 11, so that front and rear ends of the optical adapter 11 are exposed to the outside. The plug device 63 is plugged into the front end of the optical adapter 11, and the connecting head 303 of the fiber array unit 300 is detachably inserted into the internal groove 110 from the rear end of the optical adapter 11.

As shown in FIGS. 2 and 3, after being inserted, the connecting head 303 is securely supported by the internal socket 111 and remains firmly in place unless a pulling force is applied to the connecting head 303, causing a groove opening surrounded by the blocks 113 to enlarge, and allowing the connecting head 303 to disengage from the restriction imposed by the blocks 113. In this manner, the connecting head 303 can be detached from the internal socket 111, reducing spatial constraints between the optical adapter 11 and the load board 10, thus enhancing the flexibility in component arrangement on the load board 10, and improving production efficiency because the fiber array unit 300 is prepared separately from the load board 10.

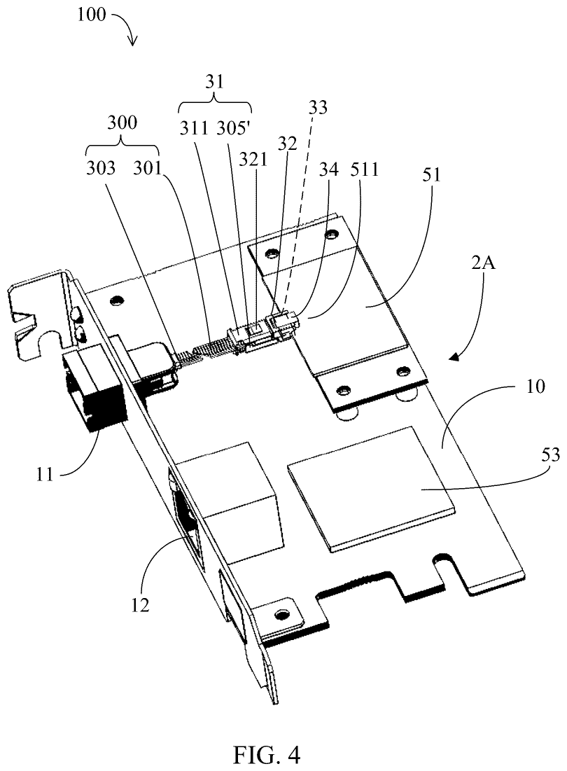

Referring to FIG. 4, showing a schematic perspective view of an optical network interface card 2A in accordance with an embodiment of the present application, the main difference between the optical network interface card 2A and the optical network interface card 1A is that the structure of the optical coupling assembly 30. As shown in FIG. 4, the optical coupling assembly 30 includes a plurality of optical fibers 301, a connecting head 303, a detachable connector 31, a connecting base 32, and a waveguide substrate 33. Specifically, the detachable connector 31 includes a ferrule element 305′ and a fastening member 311 movably assembled with the ferrule element 305′, and the connecting base 32 includes an engaging member 321. The ferrule element 305′ is positioned at ends of the optical fibers 301 away from the connecting head 303 and detachably connected to the connecting base 32. The fastening member 311 is configured to detachably engage with the engaging member 321 to further secure the connection between the ferrule element 305′ and the connecting base 32. The waveguide substrate 33 is configured to optically couple light signals between the optical fibers 301 and the photonic integrated circuit 51. In detail, the waveguide substrate 33 is positioned in the connecting base 32, in optical alignment between the optical fibers 301 and the signal transmitting portion 511 of the photonic integrated circuit 51.

In some embodiments, the waveguide substrate 33 may be made of silica or silicon depending on specific requirements. The waveguide substrate 33 may include a planar lightwave circuit (PLC), which can be configured in various ways, including, but not limited to, a straight line circuit, a splitter circuit, an arrayed waveguide grating wavelength multiplexer, and a cross connect-type circuit. Different types of waveguide circuits or devices can be utilized for the planar lightwave circuit in waveguide substrate 33 of the present application.

Still referring to FIG. 4, a bridging element 34 is installed on the connecting base 32. Specifically, part of the bridging element 34 is positioned on the waveguide substrate 33, and another part of the bridging element 34 is positioned on the photonic integrated circuit 51. The use of the bridging element 34 can enhance the structural strength of the photonic integrated circuit 51 and provide a combination force to securely integrate the waveguide substrate 33 with the photonic integrated circuit 51. Since the waveguide substrate 33 has a complex structure, the waveguide substrate 33 in this embodiment separately provided from the photonic integrated circuit 51 can improve production efficiency of the waveguide substrate 33. In some embodiments, the waveguide substrate 33 may integrally extend from the photonic integrated circuit 51, which can eliminate the need for an additional waveguide converter substrate for optical coupling and simplify the structure. In some embodiments, the bridging element 34 may be replaced with the waveguide substrate 33. Specifically, the space for the original bridging element 34 is configured for the disposition of the waveguide substrate 33, thereby achieving different types optical coupling between the photonic integrated circuit 51 and the waveguide substrate 33.

In addition, as shown in FIG. 4, the waveguide substrate 33 functioning as a medium for optically coupling the light signals can improve the stability and efficiency of optical transmission. It is noted that the material properties of the photonic integrated circuit 51 impose inherent limitations on variation of aperture values of light paths formed by direct optical coupling with the optical fibers 301, resulting in a higher susceptibility to light loss. In this embodiment, the optical fibers 301 are indirectly optically coupled to the photonic integrated circuit 51 through the waveguide substrate 33, which effectively converts the light paths into a broader and more varied range of aperture expansion values, thus reducing light loss while improving the stability and efficiency of optical transmission.

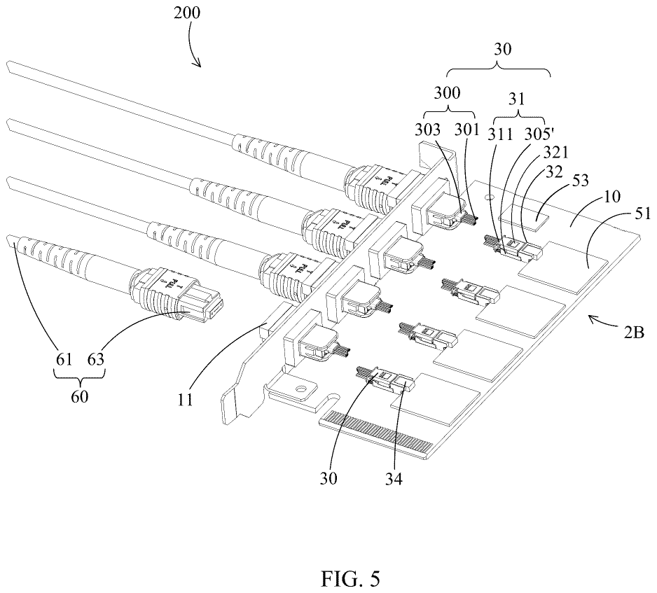

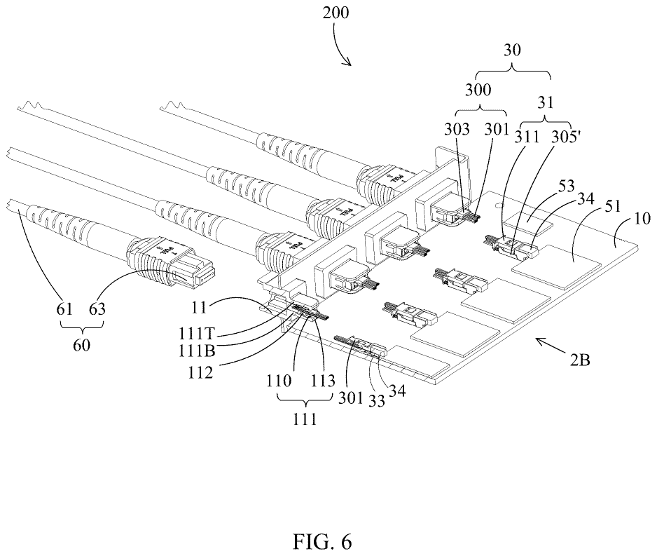

Referring to FIGS. 5 and 6, FIG. 5 is a schematic perspective view showing an optical transmission apparatus 200 in accordance with an embodiment of the present application, and FIG. 6 is a schematic cross-sectional view of FIG. 5. The main differences between the optical network interface card 2B and the optical network interface card 2A are that four optical adapters 11, four optical coupling assemblies 30, and four photonic integrated circuits 51 are provided, without the presence of the optical adapter 12 for the RJ 45 connector. As shown in FIG. 5, the optical cable units 60 have substantially the same structure as those shown in FIG. 2, which will not be described in detail here. As shown in FIG. 5, the optical cable units 60 and an optical network interface card 2B together constitute the optical transmission apparatus 200.

As shown in FIG. 6, the optical adapter 11 includes an internal socket 111 positioned over the load board 10. The internal socket 111 shown in FIG. 6 has substantially the same structure as the internal socket 111 shown in FIG. 3. Specifically, as shown in FIG. 6, the internal socket 111 includes a top wall 111T and a bottom wall 111B spaced apart and maintaining a certain height relative to the load board 10. In detail, each of the upper wall 111T and the bottom wall 111B includes a root portion 112 and a block 113. An internal groove 110 is provided between the upper wall 111T and the bottom wall 111B. The blocks 113 are symmetrically formed and protrude toward each other. After being inserted, the connecting head 303 is securely supported by the internal socket 111 and remains firmly in place unless a pulling force is applied to the connecting head 303, causing a groove opening surrounded by the blocks 113 to enlarge, and allowing the connecting head 303 to disengage from the restriction imposed by the block 113, thus being detached from the internal socket 111.

In the embodiment shown in FIGS. 4 to 6, the photonic integrated circuit 51 and the network chip 53 may be flip-chip mounted onto the load board 10. It should be noted that based on the detachable connection between the detachable connector 31 and the photonic integrated circuit 51, the assembly of the photonic integrated circuit 51 and the waveguide substrate 33 in combination with the load board 10 can proceed to a reflow process or a back-end process under high temperatures, with both the optical fibers 301 and the detachable connector 31 detached from the photonic integrated circuit 51. Therefore, the optical fibers 301 would not be damaged by the high temperatures during the above-mentioned processes.

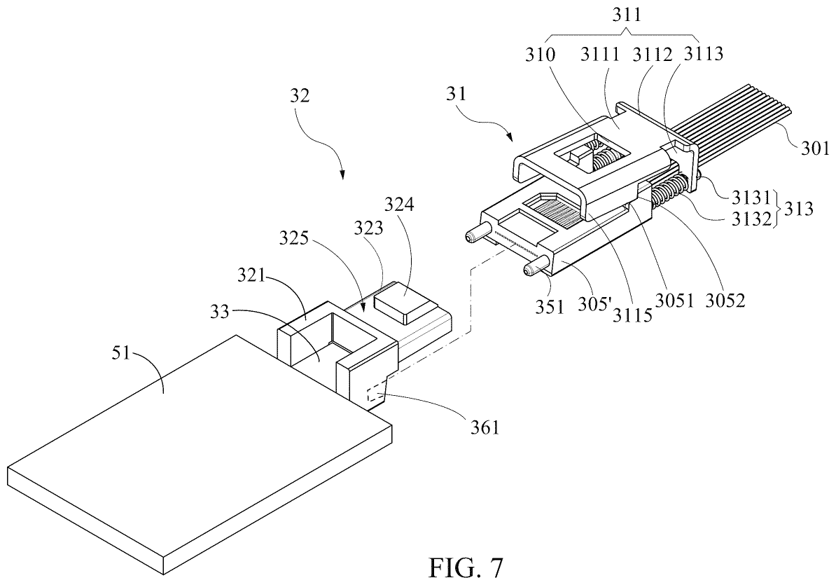

Referring to FIG. 7, which is a schematic exploded view showing the detachable connector 31 and the connecting base 32 of the optical network interface cards 2A and 2B, the detachable connector 31 includes the optical fibers 301, the ferrule element 305′, a movable fastening member 311, two limiting member 313, and two locating members 351. In some embodiments, the ferrule element 305′ includes at least a first step portion 3051 and a second step portion 3052 positioned on an upper surface of the ferrule element 305′. The second step portion 3052 adjoins the first step portion 3051 and is located higher than the first step portion 3051. The two limiting members 313 are disposed at a rear side of the ferrule element 305′ opposite to the locating members 351. In this embodiment, each of the limiting members 313 includes a limiting rod 3131 and an elastic component 3132. One end of the limiting rod 3131 is connected to a rear side of the ferrule element 305′, and the elastic component 3132, preferably a compressed spring, is positioned around the limiting rod 3131.

As shown in FIG. 7, the connecting base 32 includes a base body 321 and a retaining member 323. The retaining member 323 is tongue-like in shape and extends from the base body 321. A positioning protrusion 324 is positioned on the retaining member 323 and spaced apart from the base body 321 so that a holding space 325 is formed between the positioning protrusion 324 and the base body 321. The waveguide substrate 33 is positioned in the base body 321.

Still referring to FIG. 7, the fastening member 311 includes a hood portion 3111 positioned above the ferrule element 305′, a linking portion 3113 movably connected to the limiting rod 3131, and a bent portion 3112 connected between the hood portion 3111 and the linking portion 3113. Preferably, the hood portion 3111, the bent portion 3112, and the linking portion 3113 are a one-piece element and jointly form a substantially inverse L shape and a cantilever structure. A fastening groove 310 is formed to penetrate the hood portion 3111 and is shaped and sized to be in a snap-fit engagement with the positioning protrusion 324 of the connecting base 32. In some embodiments, the hood portion 3111 includes two wing portions 3115 disposed on two opposite sides of the hood portion 3111 and bent downward toward the ferrule element 305′. The wing portions 355 are supported on the supporting members 323, respectively, in a non-fastened state with the connecting base 32. Specifically, a rear end of the wing portion 3115 is retained against the second step portion 3052 such that the hood portion 3111 tilts with respect to the ferrule element 305′ to enlarge a space between the hood portion 3111 and the ferrule element 305′ for ease of assembly between the detachable connector 31 and the connecting base 32.

In assembly of the detachable connector 31 and the connecting base 32, the hood portion 3111 is pushed forward to move to the connecting base 32, and the pin-like locating members 351 are snugly inserted to positioning portions 361. At the same time, the hood portion 3111 is guided by the positioning protrusion 324. When the hood portion 3111 is being continuously pushed forward until it reaches the holding space 325, the hood portion 3111 is being pressed downward to allow the fastening groove 310 to be engaged with the positioning protrusion 324, so that a front part of the hood portion 3111 is positioned in the holding space 325. Concurrently, as shown in FIGS. 4 and 5, upon the positioning protrusion 324 is engaged with the hood portion 3111 in the fastening groove 310, the rear end of the wing portion 3115 is retained against the first step portion 3051, and the elastic component 3132 applies a push force on the linking portion 3113 to appropriately tighten the engagement between the hood portion 3111 and the positioning protrusion 324. In this manner, the detachable connector 31 can be easily and firmly connected with the connecting base 32.

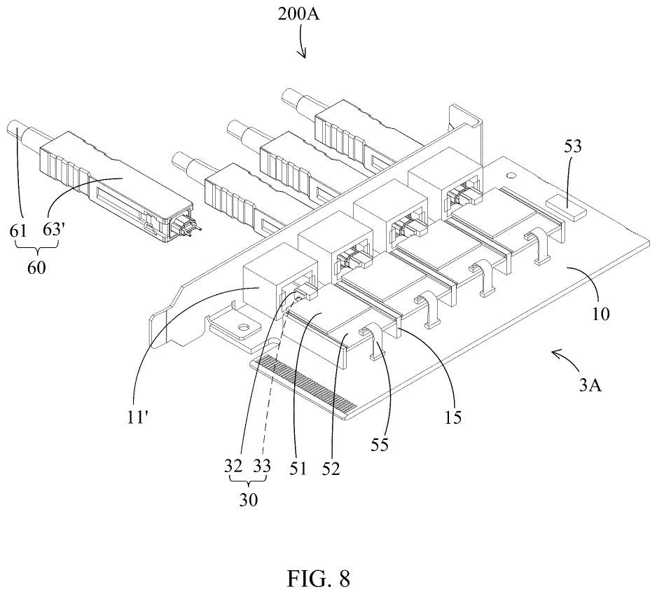

Referring to FIG. 8, illustrating a schematic perspective view showing an optical transmission apparatus 200A in accordance with an embodiment of the present application, in this embodiment, the optical coupling assembly 30 of the optical network interface card 3A eliminates the use of the fiber array unit 300 and the detachable connector 31, while remains the connecting base 32. Similarly, the waveguide substrate 33 is positioned in the connecting base 32 in optical alignment with the signal transmitting portion 511 of the photonic integrated circuit 51. Since the fiber array unit 300 and the detachable connector 31 are omitted, the size of the optical network interface card 3A can be significantly reduced, making it more compact. It should be noted that the structures of the connecting base 32 and the waveguide substrate 33 shown in FIG. 8 are substantially the same as those of the optical network interface cards 2A and 2B, which will not be described in detail here. In this embodiment, the optical network interface card 3A and a plurality of optical cable units 60 together constitute the optical transmission apparatus 200A.

As shown in FIG. 8, the optical network interface card 3A includes four optical adapters 11′, a plurality of elevated portions 15, four upper boards 52, and four flexible cables 55. Four optical cable units 60 are used to be plugged into the optical adapters 11′, respectively. It should be noted that the number of the optical cable units 60 and the optical adapters 11′ can be varied depending on specific needs. Each of the optical cable units 60 includes an optical cable 61 and a plug device 63′. The elevated portions 15 are spaced apart from each other and disposed on the load board 10 to correspond to the respective connecting bases 32. Specifically, each of the upper boards 52 is positioned between adjacent two of the elevated portions 15. The photonic integrated circuit 51 is mounted on the upper board 52, and the flexible cable 55 has one end connected to the upper board 52, and the other end connected to the load board 10 for electrical signal transmission with the load board 10. As shown in FIG. 8, the elevated portions 15 are configured to support the upper board 52 at a predetermined height above the load board 10. The predetermined height is based on the position of the plug device 63′ within the optical adapter 11′, ensuring that the waveguide substrate 33 is optically coupled to the plug device 63′.

Still referring to FIG. 8, in this embodiment, the plug device 63′ is a high-speed connector, which can improve signal transmission performance. In this embodiment, the plurality of plug devices 63′ (the high-speed connectors) of the optical cable units 60 are plugged to the optical adapters 11 to directly connect to the waveguide substrates 33, respectively. Therefore, the signal transmission distance between the waveguide substrate 33 and the optical cable unit 60 can be shortened because of the removal of the fiber array unit 300 and the detachable connector 31.

The present application further provides an optical transmission apparatus, including an aforementioned optical network interface card, including: a load board; a network chip disposed on the load board; at least an optical adapter installed on the load board; a photonic integrated circuit disposed on the load board and comprising a signal transmitting portion; and an optical coupling assembly installed on the load board and connected between the optical adapter and the signal transmitting portion; and at least an optical cable unit detachably plugged to the optical adapter and optically connected with the photonic integrated circuit through the optical coupling assembly.

Accordingly, the optical network interface card and the optical transmission apparatus are equipped with the photonic integrated circuit as the medium for light signal transmission, which eliminates the need for space to accommodate a conventional optical transceiver (not shown) connected to the optical cable, thus making the optical network interface card more compact, optimizing both the size and the efficiency of the entire optical network interface card and the optical transmission apparatus, thereby improving the utilization of the limited internal space in data processing devices.

Although the present invention has been disclosed as a preferred embodiment, it is not intended to limit the present invention. Those skilled in the art without departing from the scope of the present invention may make various changes or modifications, and thus the scope of the present invention should be after the appended claims and their equivalents.

What is claimed is:

1. An optical network interface card, adapted for use with at least an optical cable unit, and comprising:
a load board;
a network chip disposed on the load board;
at least an optical adapter installed on the load board for connection with the optical cable unit;
a photonic integrated circuit disposed on the load board and electrically connected to the network chip; and
an optical coupling assembly installed on the load board and connected between the optical adapter and the photonic integrated circuit.

2. The optical network interface card of claim 1, wherein the optical coupling assembly comprises a fiber array unit comprising a connecting head, a ferrule element, and a plurality of optical fibers connected between the connecting head and the ferrule element, wherein the connecting head is connected to the optical adapter, and the ferrule element is positioned to correspond to a transmitting portion included in the photonic integrated circuit.

3. The optical network interface card of claim 2, wherein the optical coupling assembly further comprises a detachable connector, a connecting base, and a waveguide substrate, wherein the detachable connector is detachably connected to the connecting base and comprises the ferrule element, and the waveguide substrate is positioned in the connecting base, in optical alignment between the optical fibers and the photonic integrated circuit.

4. The optical network interface card of claim 3, wherein the detachable connector further comprises a fastening member movably assembled with the ferrule element, the connecting base comprises a positioning protrusion, and the fastening member is configured to detachably engage with the positioning protrusion.

5. The optical network interface card of claim 4, wherein the detachable connector further comprises a plurality of limiting members connected between the fastening member and the ferrule element, the fastening member defines a fastening groove located above the ferrule element, and the connecting base comprises a base body and a retaining member extending from the base body, wherein the positioning protrusion is positioned on the retaining member, and the fastening groove is detachably fastened with the positioning protrusion to connect the detachable connector to the connecting base.

6. The optical network interface card of claim 1, wherein the optical coupling assembly comprises a connecting base connected between the optical adapter and the photonic integrated circuit, and a waveguide substrate positioned in the connecting base in optical alignment between the optical cable unit and the photonic integrated circuit.

7. The optical network interface card of claim 1, further comprising at least an elevated portion, an upper board, and a flexible cable, wherein the elevated portion is disposed on the load board to correspond to the optical adapter and is configured to support the upper board at a predetermined height above the load board, the photonic integrated circuit is mounted on the upper board, the flexible cable has one end connected to the upper board, and another end connected to the load board.

8. The optical network interface card of claim 1, wherein the optical adapter comprises an internal socket positioned over the load board and comprising a root portion, a block, and an internal groove positioned between the root portion and the block and exposed to the block, and the connecting head is detachably inserted into the internal groove.

9. An optical transmission apparatus, comprising:
an optical network interface card, comprising:
a load board;
a network chip disposed on the load board;
at least an optical adapter installed on the load board;
a photonic integrated circuit disposed on the load board and comprising a signal transmitting portion; and
an optical coupling assembly installed on the load board and connected between the optical adapter and the signal transmitting portion; and
at least an optical cable unit detachably plugged to the optical adapter and optically connected with the photonic integrated circuit through the optical coupling assembly.

10. The optical transmission apparatus of claim 9, wherein the optical coupling assembly comprises a fiber array unit comprising a connecting head, a ferrule element, and a plurality of optical fibers connected between the connecting head and the ferrule element, wherein the connecting head is connected to the optical adapter, and the ferrule element is positioned to correspond to a transmitting portion included in the photonic integrated circuit.

11. The optical transmission apparatus of claim 10, wherein the optical coupling assembly further comprises a detachable connector, a connecting base, and a waveguide substrate, wherein the detachable connector is detachably connected to the connecting base and comprises the ferrule element, and the waveguide substrate is positioned in the connecting base, in optical alignment between the optical fibers and the signal transmitting portion of the photonic integrated circuit.

12. The optical transmission apparatus of claim 11, the detachable connector further comprises a fastening member movably assembled with the ferrule element, the connecting base comprises a positioning protrusion, and the fastening member is configured to detachably engage with the positioning protrusion.

13. The optical transmission apparatus of claim 12, wherein the detachable connector further comprises a plurality of limiting members connected between the fastening member and the ferrule element, the fastening member defines a fastening groove located above the ferrule element, and the connecting base comprises a base body and a retaining member extending from the base body, wherein the positioning protrusion is positioned on the retaining member, and the fastening groove is detachably fastened with the positioning protrusion to connect the detachable connector to the connecting base.

14. The optical transmission apparatus of claim 9, wherein the optical coupling assembly comprises a connecting base connected between the optical adapter and the photonic integrated circuit, and a waveguide substrate positioned in the connecting base in optical alignment between the optical cable unit and the signal transmitting portion.

15. The optical transmission apparatus of claim 9, further comprising at least an elevated portion, an upper board, and a flexible cable, wherein the elevated portion is disposed on the load board to correspond to the optical adapter and is configured to support the upper board at a predetermined height above the load board, the photonic integrated circuit is mounted on the upper board, the flexible cable has one end connected to the upper board, and another end connected to the load board.

16. The optical transmission apparatus of claim 9, wherein the optical adapter comprises an internal socket positioned over the load board and comprising a root portion, a block, and an internal groove positioned between the root portion and the block and exposed to the block, and the connecting head is detachably inserted into the internal groove.

17. The optical transmission apparatus of claim 9, wherein the optical cable unit comprises an optical cable and a plug device positioned at an end of the optical cable and detachably plugged to the optical adapter.
